(19) United States
(12) Patent Application Publication
(10) Pub. No.: US 2003/0076174 A1
(43) Pub. Date: Apr. 24, 2003

(54) Radio frequency amplifier

(76) Inventors: Tomonori Tanoue, Machida (JP); Kenji Sekine, Hinode (JP); Akira Kuriyama, Kokubunji (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/273,092

(22) Filed: Oct. 18, 2002

(30) Foreign Application Priority Data
Oct. 18, 2001 (JP) 2001-320060

(51) Int. Cl. H03F 3/191

(52) U.S. Cl. 330/302

(57) ABSTRACT

In a radio frequency amplifier, a value of a matching device is changed in one matching circuit so as to constitute a matching circuit which realizes a load impedance optimized by a plurality of frequency bands, outputs, and signal modulation systems. When the matching device value is changed, a plurality of devices are connected onto the matching circuit via a micro mechanical switch. Alternatively, two points disposed apart from each other on a transmission line are connected using a micro mechanical switch. The micro mechanical switch is controlled to be on/off so that a device value or transmission line length is changed.

### BACKGROUND OF THE INVENTION

The present invention relates to a radio frequency amplifier for use in a terminal for radio-frequency mobile communication, particularly to a radio frequency amplifier for use in a plurality of frequencies, systems, or output levels.

One example of a structure of a conventional radio frequency amplifier is disclosed in JP-A-4-269013. The example will be described with reference to reference numerals of FIG. 1 of the publication. Reference numeral 21 denotes a power amplifier, 22 and 23 denote filter and matching network, 26 denotes a load impedance, and 24 and 25 are switches which switch the matching networks 22 and 23 in accordance with a type of modulation of a modulated carrier wave. The switches 24 and 25 correspond to relays, mechanical operation contacts, or electronic devices such as PIN diodes and FET.

Another example of the structure of the conventional radio frequency amplifier is disclosed in JP-A-9-232887. The example will be described with reference to reference numerals of FIG. 1 of the publication. Reference numeral 10 denotes an input matching circuit, 21 denotes a GaAs power FET, 30 and 40 denote matching networks which optimize and output an impedance of an output signal of the GaAs power FET in accordance with a frequency band, and 27 denotes a switch which changes the output matching circuit. The switch 27 corresponds to the electronic device such as a PIN diode and FET, or a filter which has a frequency selection property.

Still further example of the structure of the conventional radio frequency amplifier is disclosed in JP-A-2001-196875. The example will be described with reference to reference numerals of FIG. 1 of the publication. Reference numeral 3 denotes a gain variable device, 4a denotes amplification means, 8a and 8b denote a plurality of output matching means, 6a and 6b are changeover means for changing the output matching means connected to the amplification means 4a, and 5a denotes control means for controlling a gain of the gain variable means, operation current of the amplification means and changeover of the changeover means.

In the example of the JP-A-4-269013, when the changeover switch device is constituted of the relay or mechanical operation contact, the device has a large dimension. This causes a problem that the amplifier has a large occupying area. Moreover, when the electronic devices such as the PIN diode and FET are used, the switch device has a large electric resistance. Therefore, there are problems that the matching circuit has an increasing loss and cannot obtain a high efficiency, and that a distortion in a large signal operation of the PIN diode or FET deteriorates distortion properties of the amplifier. Moreover, two matching circuits are prepared, and this causes a problem that the occupying area of the amplifier increases.

Also in the example of the JP-A-9-232887, when the electronic devices such as the PIN diode and FET are used in the changeover switches, the electric resistance of the device is large, and therefore the loss in the matching circuit increases. Additionally, the distortion in the large signal operation of the PIN diode or FET deteriorates the distortion property of the amplifier. This causes a problem that a high efficiency cannot be obtained. Moreover, with the use of the filter in the changeover, a problem is that the dimension of the amplifier increases. Furthermore, since two matching circuits are prepared, the occupying area of the amplifier disadvantageously increases.

Further in the example of the JP-A-2001-196875, when the electronic devices such as the PIN diode and FET are used in the changeover switches, the electric resistance of the device is large, and therefore the loss in the matching circuit increases. Additionally, the distortion in the large signal operation of the PIN diode or FET deteriorates the distortion property of the amplifier. This causes a problem that the high efficiency cannot be obtained. It is also described that to change the impedance of the matching circuit, devices having continuously changing device values, such as a varactor diode can be used. However, to correctly control the device value, the value of a control voltage needs to precisely be set. This causes a problem that a circuit scale needlessly increases. Furthermore, two matching circuits are prepared, and this causes a problem that the occupying area of the amplifier increases.

### SUMMARY OF THE INVENTION

An object of the present invention is to solve the above-described problems and to provide a small radio frequency amplifier which realizes a high efficiency in a plurality of frequencies, systems, or output power levels.

In order to constitute a matching circuit which realizes a load impedance optimized by a plurality of frequency bands, output power levels, and signal modulation systems, a radio frequency amplifier according to the present invention realizes it by changing a value of a matching device in one matching circuit without using a plurality of independent matching circuits. To change the matching device value, without using a device whose device value continuously changes such as a varactor diode, a plurality of devices are connected via a micro mechanical switch on the matching circuit, or two points apart from each other on a transmission line are connected using the micro mechanical switch. When the micro mechanical switch is controlled to be on/off, the device value or transmission line length is changed. Here, the micro mechanical switch is a switch prepared by means similar to means for preparing a semiconductor integrated circuit, that is, means for repeatedly depositing an insulating film and electrically conductive film on a substrate and processing the films using photolithography and chemical/physical etching. A dimension of the switch is in a range of several to several hundreds of micrometers in an in-plane direction of the prepared substrate, or one micrometer or less to several tens of micrometers in a vertical direction with respect to the substrate. Moreover, examples of a driving method for use can include electrostatic driving, electromagnetic driving, piezoelectric driving by a piezo device, and driving by bimetal constituted by attaching a heating material to a plurality of materials different in a coefficient of thermal expansion. In this manner, the micro mechanical switch is different from a general relay or mechanical switch in the preparation method, dimension, and energy necessary for the driving.

Concretely, a radio frequency amplifier according to the present invention comprises: an amplifier for amplifying and outputting a transmission signal; and a mechanical switch for changing a value of a matching circuit device included in an output matching circuit of the amplifier, wherein the mechanical switch is turned on/off so as to change a matching impedance of the output matching circuit. By the change of the matching impedance, the transmission signals of a plurality of frequency bands can be amplified. Alternatively, with the change of the matching impedance, a saturated output level of the amplifier changes.

Here, the amplifier includes a constitution of a plurality of stages. Amplification stages other than a final stage among the plurality of stages have an amplification bandwidth extending over a plurality of frequency bands, and the final stage may have a bandwidth narrower than the amplification bandwidth extending over the plurality of frequency bands.

Moreover, a radio frequency amplifier according to the present invention comprises: an amplifier constituted of a plurality of stages, for amplifying a transmission signal of a multimode cellular phone; and a mechanical switch for changing a value of a matching circuit device included in an output matching circuit of a final stage of the amplifier, wherein the mechanical switch matches the output matching circuit with a transmission frequency or output level of the transmission signal.

More concretely, a radio frequency amplifier according to the present invention comprises: a first amplifier including a first node for inputting a transmission signal and a first output matching circuit, the first amplifier amplifying the transmission signal inputted via the first node to output the amplified transmission signal via the first output matching circuit; a second amplifier including a second node for inputting an output signal of the first amplifier and a second output matching circuit, the second amplifier amplifying the output signal inputted via the second node to output the amplified output signal via the second output matching circuit; and a third amplifier including a third node for inputting an output signal of the second amplifier, a third output matching circuit capable of matching the transmission signal of a band narrower than bands of the first and second output matching circuits, and a mechanical switch for changing a value of a matching circuit device included in the third output matching circuit, said third amplifier amplifying the output signal inputted via the third node to outputs the amplified output signal via the third output matching circuit, wherein the mechanical switch turns on/off so as to match the value of the matching circuit device of the third output matching circuit with a transmission frequency or output level of the transmission signal.

Alternatively, the amplifier further comprises: a second amplifier including a second node for inputting a transmission signal and a second output matching circuit, said second amplifier amplifying the transmission signal inputted via the second node to output the amplified transmission signal via the second output matching circuit; and a third amplifier including a third node for inputting an output signal of the second amplifier, a third output matching circuit capable of matching the transmission signal of a band narrower than a band of the second output matching circuit, and a mechanical switch for changing a value of a matching circuit device included in the third output matching circuit, the third amplifier amplifying the output signal inputted via the third node to output the amplified output signal via the third output matching circuit, wherein the mechanical switch turns on/off so as to match the value of the matching circuit device of the third output matching circuit with a transmission frequency or output level of the transmission signal.

Furthermore, a radio frequency amplifier according to the present invention comprises: a first amplifier system constituted of a plurality of stages, for amplifying a first transmission signal of a single frequency band; and a second amplifier system including an amplifier constituted of a plurality of stages, for amplifying a plurality of transmission signals of a plurality of frequency bands, and a mechanical switch for changing a value of a matching circuit device included in an output matching circuit of a final stage of the amplifier, wherein the mechanical switch matches the output matching circuit with a transmission frequency or output level of at least two transmission signals among the plurality of transmission signals.

Here, the single frequency band is a GSM band, and a plurality of frequency bands may include DCS, PCS and W-CDMA bands.

Furthermore, in the above-described constitutions, a micro mechanical switch may be used as the mechanical switch. In this case, the micro mechanical switch may be processed using photolithography and etching similar to those for use in preparing a semiconductor integrated circuit, and integrated on an amplifier substrate, or integrated with a transistor for amplification.

According to the radio frequency module of the present invention, since a plurality of load impedances are realized by changing a device constant of one matching circuit without using a plurality of matching circuits, an increase of a circuit occupying area can be avoided. Moreover, the device value is changed by the switch. Therefore, it is also unnecessary to precisely set a control voltage, which is necessary in controlling the device having a continuously changing device value. Furthermore, the micro mechanical switch is a switch which basically includes a metal contact. Therefore, it is possible to suppress generation of a signal distortion based on nonlinear properties of a semiconductor device during a large signal operation, or generation of a loss by a resistance component of the device, which has been a problem with the use of electron switches such as a semiconductor switch.

Other objects, features and advantages of the invention will become apparent from the following description of the embodiments of the invention taken in conjunction with the accompanying drawings.

### BRIEF DESCRIPTION OF THE DRAWINGS

FIG. 1 is a circuit diagram showing a first embodiment.

FIG. 2 is a plan view showing the first embodiment.

FIG. 3 is a frequency characteristic diagram of a gain according to the first embodiment.

FIGS. 4A and 4B show an impedance of a matching circuit according to the first embodiment.

FIG. 5 is a circuit diagram showing a second embodiment.

FIG. 6 is a structure diagram showing the second embodiment.

FIG. 7 is a plan view of an amplifier according to a third embodiment.

FIG. 8 is a circuit diagram showing a fourth embodiment.

FIG. 9 is a circuit diagram showing the fourth embodiment.

### DESCRIPTION OF THE EMBODIMENTS

A radio frequency power amplifier module will be described hereinafter in detail as an embodiment of the present invention with reference to the drawings.

<First Embodiment>

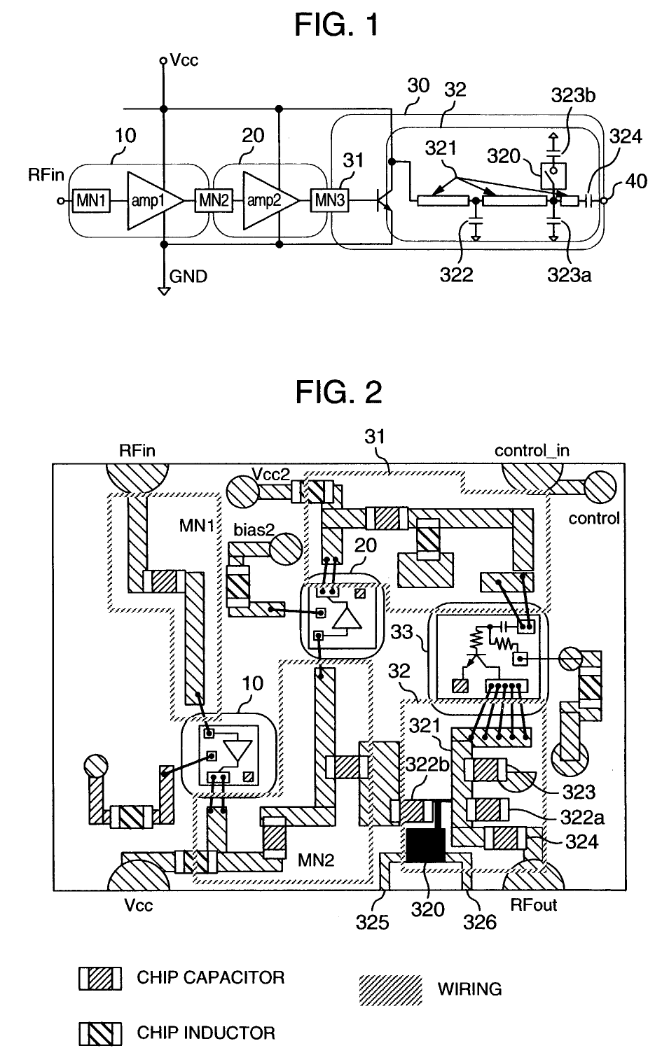

First, a constitution of a two-bands radio frequency amplifier according to the present invention will be described with reference to FIGS. 1 and 2. FIG. 1 shows a circuit diagram of a first embodiment of the present invention, and FIG. 2 shows a plan view of the first embodiment. In FIGS. 1 and 2, reference numeral 10 denotes a first stage of an amplifier, 20 denotes a second stage of the amplifier, 30 denotes a third stage of the amplifier, 31 denotes a third-stage input matching circuit of the amplifier, 32 denotes an output matching circuit of the amplifier, and 33 denotes a power transistor as amplification means of the third stage of the amplifier. Reference numeral 321 denotes a major transmission line of the output matching circuit 32, numerals 322, 323a, 323b and 324 denote capacitors disposed in the output matching circuit of the amplifier, and numeral 320 denotes a micro mechanical switch disposed between the capacitor 323b and the major transmission line 321. Here, the micro mechanical switch is a switch prepared by means similar to means for preparing a semiconductor integrated circuit, that is, means for repeatedly depositing an insulating film and electrically conductive film with respect to a substrate and processing the films using photolithography and chemical/physical etching. A dimension of the switch is in a range of several to several hundreds of micrometers in an in-plane direction of the prepared substrate, or one micrometer or less to several tens of micrometers in a vertical direction with respect to the substrate. Moreover, examples of a driving method for use can include electrostatic driving, electromagnetic driving, piezoelectric driving by a piezo device, and driving by bimetal constituted by attaching a heating material to a plurality of materials different in a coefficient of thermal expansion. In this manner, the micro mechanical switch is different from a general relay or mechanical switch in the preparation method, dimension, and energy necessary for the driving. Reference numerals 325 and 326 denote driving electrodes of the micro mechanical switch 320, and 40 denotes an output terminal. An amplifier substrate 100 is formed of alumina ceramic. The power transistor 33 is a GaAs hetero junction bipolar transistor, thinned down to 100 micrometers of a substrate thickness so as to achieve satisfactory heat release, subsequently bonded to the amplifier substrate 100 by a silver epoxy paste, and connected to the matching circuit 32 on the amplifier substrate by wire bonding. Moreover, the micro mechanical switch 320 is constituted on the amplifier substrate by means similar to means for preparing the semiconductor integrated circuit. The capacitors 322, 323a, 323b and 324 in the matching circuit are mounted on the amplifier substrate 100 by soldering.

An operation of the two-bands radio frequency amplifier will be described hereinafter with reference to FIG. 1.

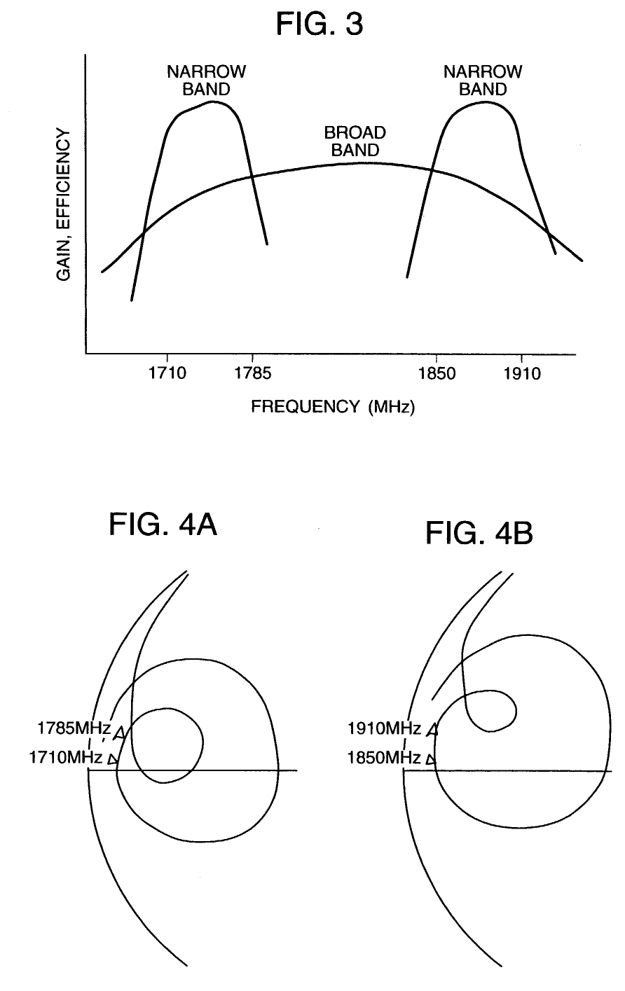

The two-bands amplifier according to the present invention is an amplifier of two frequency bands including a cellular phone system GSM1800 (frequency band of 1710 to 1785 MHz) for use in Europe, cellular phone system PCS (frequency band of 1850 to 1910 MHz) for use in the U.S. In FIG. 1, the first stage 10 and second stage 20 of the amplifier correspond to broadband amplifiers which can sufficiently amplify the above-described two frequency bands and which have a frequency band of about 1680 to 1950 MHz. On the other hand, the third-stage amplifier 30 is designed to have a band width of about 50 MHz. This is because efficiency of the third stage is deteriorated by a broadband design. FIG. 3 shows frequency band characteristics of gains of the first/second-stage amplifier and third-stage amplifier. The output of the amplifier needs to be about 33 dBm in either system GSM 1800 or PCS. For the efficiency of the amplifier in the output of 33 dBm, an efficiency of about 40 to 45% including an assembly dispersion is obtained with the broad band design, and an efficiency of 50 to 55% is obtained with a design in a band of about 50 MHz.

The micro mechanical switch 320 is used to match the amplifier with a narrow band of about 50 MHz with two different bands of 100 MHz or more. The matching capacitors 322, 323a and 324 are constantly connected to the major transmission line 321. While the switch 320 is in an off state, the matching circuit is matched with the PCS band having a high frequency. Here, when the switch 320 is turned on, the matching capacitors 323a and 323b connected to the major transmission line 321 in the same position are added and a phase rotation in the matching circuit increases. Therefore, the switch 320 is matched at a frequency lower than a frequency in the off state. This is shown in FIGS. 4A and 4B. FIGS. 4A and 4B are Smith charts showing a complex impedance, assuming the output matching circuit 32 terminated at 50 ohms from an output end of the power transistor 33. FIG. 4A shows the off state of the switch 320, and FIG. 4B shows the on state of the switch 320. Markers in the drawing show reflections in upper and lower ends of the PCS and GSM 1800 bands. As apparent from the drawings, a reflection coefficient of the GSM 1800 band in the switch-on-state overlaps with that of the PCS band in the switch-off-state, and it is expected that the equal output/efficiency is obtained in both the bands. In actual, the same efficiency/output is obtained in a range of device dispersions in either the PCS or GSM 1800 band, that is, an efficiency of 50 to 55% is obtained in an output of 33 dBm.

Therefore, according to the present embodiment, a high efficiency can be obtained as compared with a broad-range matching in a plurality of frequency bands

In the present embodiment, the hetero junction bipolar transistor is used as the power transistor. An essential property of the present invention lines in that the impedance of the matching circuit is changed by the micro mechanical switch. Of course, the similar effect is obtained even using Si bipolar transistor, Si-MOSFET, GaAs-FET, and the like. Moreover, in the present embodiment, the two-bands amplifier for the GSM 1800 and PCS has been described. Needless to say, the band can be expanded in a similar manner also with other two-bands amplifier such as an amplifier for a combination of GSM 1800 and W-CDMA (1920 MHz to 1980 MHz), or a three-bands amplifier for GSM 1800, PCS and W-CDMA.

<Second Embodiment>

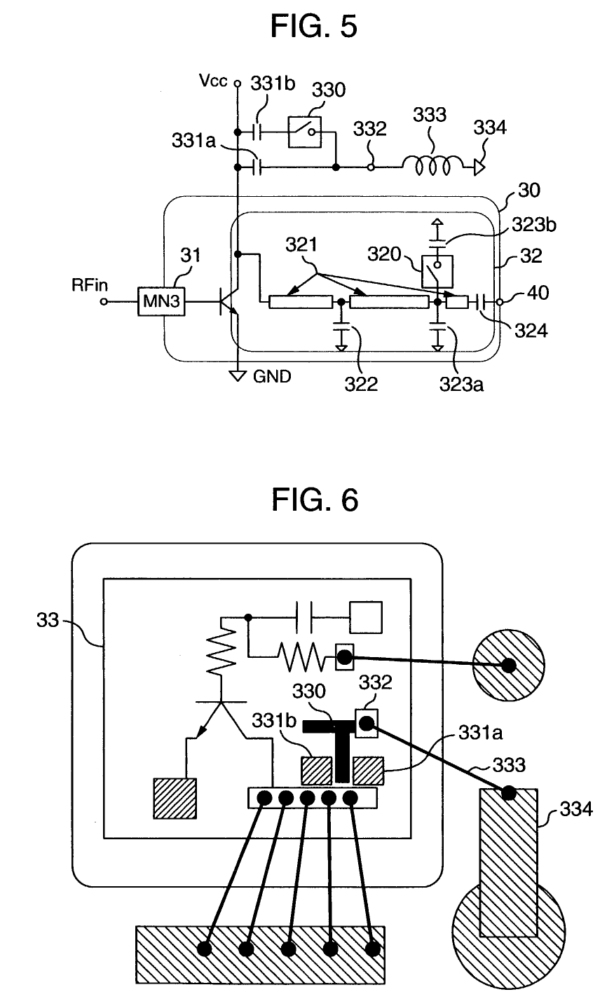

A constitution of a second embodiment of the present invention will be described with reference to FIGS. 5 and 6. FIG. 5 is a circuit diagram of a part corresponding to an output part of the power transistor shown in FIG. 1, and FIG. 6 is an enlarged view of the constitution of the corresponding part. In FIG. 6, integrated capacitors 331a and 331b are connected to an output pad portion on a semiconductor chip constituting the power transistor 33, and the capacitor 331a is directly connected to a bonding pad 332. The capacitor 331b is connected to the same bonding pad 332 via a micro mechanical switch 330 integrated on the power transistor chip. The bonding pad 332 is connected to a ground pad 334 on the amplifier substrate 100 via a bonding wire 333. A capacitance of the integrated capacitor 331a is set so that a series resonant frequency with inductance of the bonding wire 333 becomes substantially twice an amplified signal frequency. A load impedance substantially has a short circuit with respect to a second higher harmonic wave generated by a nonlinear distortion of the amplifier. When a second higher harmonic signal returns to the transistor, the efficiency is enhanced. A so-called second higher harmonic trap is thus formed. When a plurality of frequency bands are switched and amplification is performed in the output matching circuit 32, the second higher harmonic frequency also changes. It is therefore necessary to change the device constant of the second higher harmonic trap. For the second higher harmonic trap, when the impedance anticipated from the power transistor is in a condition close to the above-described short circuit, the efficiency is maximized. When a series resonance of capacitor and inductor is used as in the present embodiment, the trap needs to be disposed right in the vicinity of a power transistor output. Therefore, as described in the present embodiment, it is optimum to use the integrated capacitor in the power transistor. Moreover, the micro mechanical switch 330 integrated with the power transistor is used in changing the frequency of the higher harmonic trap. Furthermore, the micro mechanical switch 330 is turned on/off in synchronization with the switching of the matching frequency of the matching circuit, and the frequency of the second higher harmonic trap is also simultaneously changed, so that a high efficiency can be realized. When the resonance frequency of the second higher harmonic trap is changed in synchronization with the signal frequency, the amplifier efficiency is enhanced by 3%. Since a preparation step of the power transistor includes insulating film deposition, metal conductive film deposition, and chemical/physical processing of the films, it is easy to integrate the micro mechanical switch. In general, it is possible to process the films in a semiconductor chip manufacturing process more finely than an amplifier substrate manufacturing process. For the micro mechanical switch 330 integrated with the power transistor, a small-sized high-precision switch can be obtained as compared with the micro mechanical switch disposed on the amplifier substrate. Therefore, a higher harmonic wave trap having a low loss can be realized as compared with a fourth embodiment in which the micro mechanical switch for changing the resonance frequency of the higher harmonic wave trap is disposed on the amplifier substrate as described later.

<Third Embodiment>

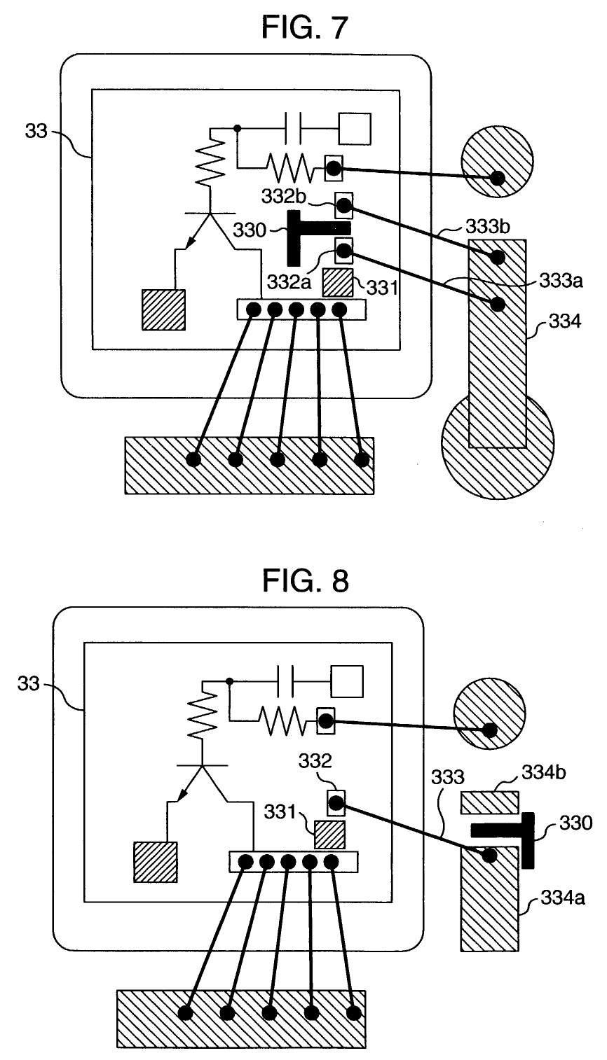

FIG. 7 shows another embodiment of the radio frequency amplifier according to the present invention. The bonding pad 332 of the second higher harmonic trap in the second embodiment is divided, and a plurality of pads 332a and 332b are connected to the ground pad 334 via bonding wires 333a and 333b. The bonding pads 332a and 332b are connected to each other via a micro mechanical switch 330a. As described above, the resonance frequency of the second higher harmonic trap is determined by the value of the integrated capacity and the inductance of the bonding wire. Therefore, when the switch 330a is turned on/off to change the number of bonding wires connected in parallel, the resonance frequency can be changed. The present embodiment has an advantage that lengths of the bonding wires 333a and 333b can be adjusted to control the resonance frequency. Therefore, when the characteristics of the amplifier substrate 100 are not obtained as desired, the resonance frequency can advantageously be changed in a mounting stage. The present embodiment is effective under a circumstance under which manufacturing dispersions do not raise a large problem.

<Fourth Embodiment>

FIG. 8 shows another embodiment of the radio frequency amplifier according to the present invention. FIG. 8 is a circuit diagram of a part corresponding to an output part of the power transistor, and corresponds to FIG. 5. Two integrated capacitors 331a and 331b disposed in the second embodiment is replaced with one integrated capacitor 331. Instead, another ground pad 334b is disposed adjacent to a ground pad 334a on the amplifier substrate 100, and the pads are connected to each other via a micro mechanical switch 330b. The ground pads 334a and 334b are connected to a ground inside the substrate via via-holes. The value of the inductance which determines the resonance frequency in a case in which the signal is grounded via a plurality of ground pads (334a and 334b) is different from that in a case in which the signal is grounded via only one ground pad 334a. Therefore, when the switch 330b is turned on/off, the resonance frequency of the second higher harmonic trap changes. When this is used, it is possible to tune the second higher harmonic trap every bands.

<Fifth Embodiment>

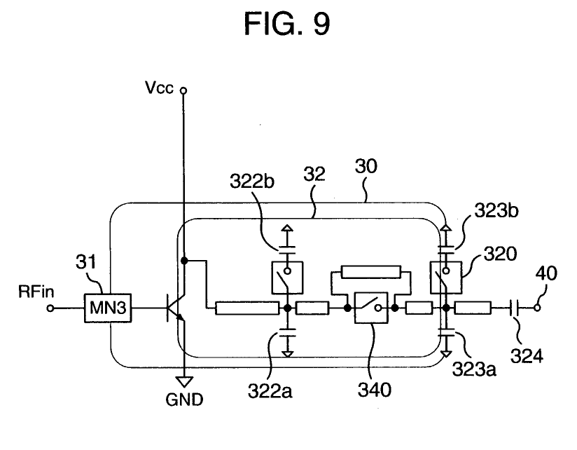

FIG. 9 shows another embodiment of the radio frequency amplifier according to the present invention. In the present embodiment, not only the capacitance but also the transmission line length are used as the value of the matching circuit device, and changed using the switches, so that a variable range of the frequency broader than that in the first embodiment are obtained. Concretely, the transmission line between the capacitors 322a and 323b is short-circuited with the micro mechanical switch, so that the ratio of the maximum length to the minimum length can be varied to about 1:2. The capacitors 322b and 323b having substantially the same capacitance are connected in parallel via the micro mechanical switch with respect to the capacitors 322a and 323b, so that the capacitance is substantially doubled. Thereby, the matching frequency range is expanded and substantially doubled. Moreover, for the matching device 324, the self resonance frequency of a capacity component needs to change to be substantially doubled. For the capacitance, about seven times the capacity is disposed in parallel, so that the self resonance frequency can be lowered to about ½. Thereby, the amplifier for two frequency bands of GSM 900 (876 to 915 MHz), and GSM 1800 whose band is about double the GSM 900 is realized by one amplifier.

The present invention applied to the radio frequency power amplifier for use in a terminal for radio frequency mobile communication has mainly been described above, but is not limited to this, and can also be applied to a general radio frequency amplifier having a narrow band, such as a driver amplifier in a previous stage of a power amplifier.

According to the radio frequency amplifier of the present invention, an amplifier module for amplifying signals of a plurality of frequencies, output levels, and modulation signal systems can be constituted by the number of radio frequency amplifiers, which is smaller than the number of frequencies, output levels, or modulation signal systems. This produces an effect that the amplifier module can be miniaturized.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A radio frequency amplifier comprising:
an amplifier for amplifying and outputting a transmission signal; and
a mechanical switch for changing a value of a matching circuit device included in an output matching circuit of said amplifier,
wherein said mechanical switch is turned on/off so as to change a matching impedance of said output matching circuit; and
the transmission signal of a plurality of frequency bands is amplified by changing said matching impedance.

2. A radio frequency amplifier comprising:
an amplifier for amplifying and outputting a transmission signal; and
a mechanical switch for changing a value of a matching circuit device included in an output matching circuit of said amplifier,
wherein said mechanical switch is turned on/off so as to change a matching impedance of said output matching circuit; and
a saturated output level of said amplifier changes by changing-said matching impedance.

3. The radio frequency amplifier according to claim 1, wherein
said amplifier is constituted of a plurality of stages;
an amplification stage other than a final stage among said plurality of stages has an amplification bandwidth extending over said plurality of frequency bands; and
the final stage has a bandwidth narrower than the amplification bandwidth extending over said plurality of frequency bands.

4. A radio frequency amplifier comprising:
an amplifier constituted of a plurality of stages, for amplifying a transmission signal of a multimode cellular phone; and
a mechanical switch for changing a value of a matching circuit device included in an output matching circuit of a final stage of said amplifier,
wherein said mechanical switch matches said output matching circuit with a transmission frequency or output level of said transmission signal.

5. A radio frequency amplifier comprising:
a first amplifier including a first node for inputting a transmission signal and a first output matching circuit, said first amplifier amplifying the transmission signal inputted via said first node to output the amplified transmission signal via said first output matching circuit;
a second amplifier including a second node for inputting an output signal of said first amplifier and a second output matching circuit, said second amplifier amplifying the output signal inputted via said second node to output the amplified output signal via said second output matching circuit; and
a third amplifier including a third node for inputting an output signal of said second amplifier, a third output matching circuit capable of matching the transmission signal of a band narrower than bands of said first and second output matching circuits, and a mechanical switch for changing a value of a matching circuit device included in said third output matching circuit, said third amplifier amplifying the output signal inputted via said third node to output the amplified output signal via said third output matching circuit,
wherein said mechanical switch turns on/off so as to match the value of the matching circuit device of said third output matching circuit with a transmission frequency or output level of said transmission signal.

6. A radio frequency amplifier comprising:
a second amplifier including a second node for inputting a transmission signal and a second output matching circuit, said second amplifier amplifying the transmission signal inputted via said second node to output the amplified transmission signal via said second output matching circuit; and
a third amplifier including a third node for inputting an output signal of said second amplifier, a third output matching circuit capable of matching the transmission signal of a band narrower than a band of said second output matching circuit, and a mechanical switch for changing a value of a matching circuit device included in the third output matching circuit, said third amplifier amplifying the output signal inputted via said third node to output the amplified output signal via said third output matching circuit,
wherein said mechanical switch turns on/off so as to match the value of the matching circuit device of said third output matching circuit with a transmission frequency or output level of said transmission signal.

7. A radio frequency amplifier comprising:
a first amplifier system constituted of a plurality of stages, for amplifying a first transmission signal of a single frequency band; and
a second amplifier system including an amplifier constituted of a plurality of stages to amplify a plurality of transmission signals of a plurality of frequency bands, and a mechanical switch for changing a value of a matching circuit device included in an output matching circuit of a final stage of the amplifier,
wherein said mechanical switch matches said output matching circuit with a transmission frequency or output level of at least two transmission signals among said plurality of transmission signals.

8. The radio frequency amplifier according to claim 7, wherein
said single frequency band is a GSM band; and
said plurality of frequency bands include DCS, PCS and W-CDMA bands.

9. The radio frequency amplifier according to claim 1 wherein said mechanical switch includes a micro mechanical switch.

10. The radio frequency amplifier according to claim 9 wherein said micro mechanical switch is processed using photolithography and etching similar to photolithography and etching for use in preparing a semiconductor integrated circuit, and integrated on an amplifier substrate.

11. The radio frequency amplifier according to claim 9 wherein said micro mechanical switch is processed using photolithography and etching similar to photolithography and etching for use in preparing a semiconductor integrated circuit, and integrated together with a transistor for amplification.
